(19) United States
(12) Patent Application Publication
(10) Pub. No.: US 2008/0238303 A1
(43) Pub. Date: Oct. 2, 2008

(54) ORGANIC LIGHT EMITTING DISPLAY DEVICE HAVING DESICANT LAYER AND METHOD OF MANUFACTURING THE SAME

(76) Inventors: Dong- Won LEE, Seongnam-si (KR); Hoon Kim, Hwaseong-si (KR); Won-Hoe Koo, Suwon-si (KR); Sang-Woo Lee, Suwon-si (KR); Jung-Mi Choi, Yongin-si (KR)

Correspondence Address: MACPHERSON KWOK CHEN & HEID LLP, 2033 GATEWAY PLACE, SUITE 400, SAN JOSE, CA, 95110, US

(21) Appl. No.: 12/014,459

(22) Filed: Jan. 15, 2008

(30) Foreign Application Priority Data
Mar. 30, 2007 (KR) 10-2007-0031427

(51) Int. Cl. H01L 27/28; H01J 9/02

(52) U.S. Cl. 313/504; 445/24

(57) ABSTRACT

An organic light emitting display device includes: an organic light emitting pixel unit having a first electrode, an organic light emitting layer, and a second electrode, formed on a substrate; where a first anti-moisture protective layer is formed on the upper surface of the second electrode; and a second anti-moisture protective layer is formed on the upper surface of the first protective layer, where the second protective layer includes desiccant particles of diameters including a predetermined maximum diameter and where the first protective layer is substantially devoid of desiccant particles having the predetermined maximum diameter or larger, and the first protective layer has a thickness substantially greater than the predetermined maximum diameter.

### CROSS-REFERENCE TO RELATED APPLICATION

This application claims priority from Korean Patent Application No. 10-2007-0031427, filed on Mar. 30, 2007, the disclosure of which is incorporated herein by reference in its entirety.

### BACKGROUND

1. Field of Disclosure

The present disclosure of disclosure relates to an organic light emitting display (OLED) device and, more particularly, to an organic light emitting display device having a desiccant layer and to methods of manufacturing the same.

2. Description of Related Technology

One of the core technologies in the information and communication era is that of an image display device which can display a variety of information on a user-viewable screen. A general desire in the technology is to develop improved display devices that are thinner, lighter, more portable, more reliable and provide higher performance than preceding generations of devices. Accordingly, various flat panel display devices, including organic light emitting display (OLED) devices are being developed to reduce weight and volume, which are drawbacks of the older cathode ray tube (CRT) technologies.

In a classic OLED device, electrons and holes are respectively injected from an electron injection electrode (cathode) and a hole injection electrode (anode) into an emissive layer. The injected charge carriers combine with each other in the emissive layer and generate excitons, where the excitons emit light while transitioning from an excited energy state to a ground state.

When compared against competing flat panel technologies, OLED devices offer advantages such as low driving voltage, low power consumption, light weight, and natural color display. However they also have the problem of a comparatively shorter lifespan. One of the factors affecting the lifespan of the OLED device is oxidation due to permeation of oxygen and/or moisture into the device.

A conventional OLED device comprises an organic light emitting pixel unit having a thin film transistor (TFT), an electron injection electrode, an organic light emitting layer, and a hole injection electrode, where these are integrally formed on a substrate. An anti-moisture protective layer is provided for protecting the organic light emitting pixel unit moisture, and a protective substrate is bonded to the substrate.

The anti-moisture protective layer includes desiccant particles of varying diameters for removing or retaining moisture that manages to permeate into the device from the outside. The anti-moisture protective layer is formed on the overall surface of the substrate to increase the lifespan of the organic light emitting pixel unit. In this case, due to their variations in size, the desiccant particles can cause spot depressions in an underlying layer due to the pressure exerted from the top when the substrate is bonded to the anti-moisture protective substrate. The spot depressions of the underlying layer can cause an electrical failure in which the electron injection electrode is shorted into contact with the hole injection electrode due to the pressurization of desiccant particles, thus resulting in a pixel defect in which the organic light emitting pixel unit does not emit light.

### SUMMARY

The present disclosure of disclosure provides an organic light emitting display (OLED) device and a method of manufacturing the organic light emitting display device in a manner which prevents or reduces the likelihood of formation of spot depressions and deformations of electrodes due to presence of desiccant particles near such locations and thus prevents a pixel defect due to the undesirable shorting contact between the electron injection electrode and the hole injection electrode of the pixel units in the OLED device.

In one exemplary embodiment, an organic light emitting display (OLED) device includes: an organic light emitting pixel unit having a first electrode, an organic light emitting layer, and a second electrode, formed on a substrate; a first protective layer that is substantially free of any desiccant particles where the first protective layer is formed on an upper surface of the second electrode; and where a second protective layer that includes desiccant particles is thereafter formed on the first protective layer. The first protective layer is composed of a sealant material with sufficient elasticity or plasticity to thus act as a buffer against spot depressions caused by compression of desiccant particles present in the second protective layer.

The organic light emitting display device may further include a protective substrate that is compressively bonded to the second protective layer.

The first protective layer may be formed of a sealant.

The second protective layer including the desiccant particles may also be formed of a sealant.

The sealant material of the second protective layer may include a same sealant material as used in the first protective layer. For example, the sealant of the second protective layer may be formed of a same epoxy-based resin as the sealant of the first protective layer.

The sealant of the second protective layer may be formed of a different material from that of the sealant of the second protective layer. For example, the sealant of the second protective layer may be formed of a different epoxy-based resin from that of the first protective layer.

The first protective layer should be formed with a thickness greater than the largest normal diameters of the desiccant particles.

The desiccant particles may be formed of at least one of a talc and a silica gel.

In one exemplary embodiment, an organic light emitting display device includes: an organic light emitting diode, including a first electrode, an organic light emitting layer, and a second electrode, formed on a substrate; and a protective layer, including desiccant particles, formed on the upper surface of the second electrode, wherein the desiccant particles are spaced apart at least 5 μm above the upper surface of the second electrode.

The organic light emitting display device may further include a protective substrate bonded to the substrate with the protective layer disposed therebetween.

In one exemplary embodiment, a method of manufacturing an organic light emitting display device includes: forming an organic light emitting pixel unit on a substrate, the organic light emitting pixel unit including a driving thin film transistor, a switching thin film transistor, a first electrode, an organic light emitting layer, and a second electrode, forming a first protective layer on the upper surface of the organic light emitting pixel unit; and forming a second protective layer in which desiccant particles are distributed on the upper surface of the first protective layer.

The process of forming the organic light emitting pixel unit may include: forming the driving thin film transistor and the switching thin film transistor on the substrate; forming a passivation layer to cover the driving thin film transistor and the switching thin film transistor, and a color filter on the upper surface of the passivation layer; forming a planarization layer including first to third contact holes on the upper surface of the passivation layer and the color filter; forming a transparent conductive pattern including a connection electrode and the first electrode on the upper surface of the planarization layer; forming a barrier layer on the upper surface of the planarization layer and the connection electrode, and the organic light emitting layer on the upper surface of the first electrode; and forming the second electrode on the upper surface of the barrier layer and the organic light emitting layer.

The method of manufacturing an organic light emitting display device may further include forming a protective substrate on the upper surface of a second protective layer that contains desiccant particles, after forming the second protective layer on top of a first protective layer that is substantially free of desiccant.

The first protective layer may be formed of a sealant on the upper surface of the second electrode.

The second protective layer may include a sealant and the desiccant particles.

The sealant of the second protective layer may be formed of a same epoxy-based resin as the sealant of the first protective layer.

The sealant of the second protective layer may be formed of a different epoxy-based resin from the sealant of the first protective layer.

### BRIEF DESCRIPTION OF THE DRAWINGS

The above and other features of the present disclosure will be described in reference to certain exemplary embodiments depicted in the attached drawings in which:

FIG. 1 is a plan view of an organic light emitting display (OLED) device in accordance with a first exemplary embodiment of the present disclosure;

FIG. 2 is a cross-sectional view taken along line I-I′ of FIG. 1;

FIG. 3 is a cross-sectional view of an organic light emitting display device in accordance with a second exemplary embodiment of the present disclosure;

FIG. 4 is a cross-sectional view of an organic light emitting display device in accordance with a third exemplary embodiment of the present disclosure; and

FIGS. 5A to 5M are cross-sectional views illustrating methods of manufacturing an organic light emitting display device in accordance with exemplary embodiments of the present disclosure.

### DETAILED DESCRIPTION

Reference will now be made in detail to exemplary embodiments of the present disclosure, depictions of which are illustrated in the accompanying drawings, wherein like reference numerals refer to generally alike elements throughout. The embodiments are described below in order to explain the present disclosure by referring to the figures.

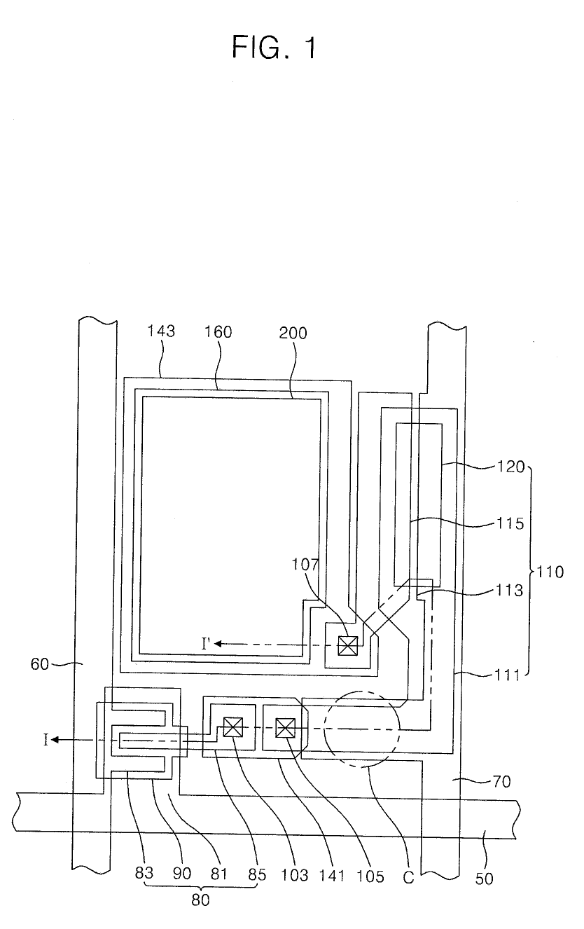

Hereinafter, exemplary embodiments of the present disclosure will now be described in detail with reference to FIGS. 1 to 5M. In the drawings, the thickness of layers and regions may be exaggerated for purpose of illustrative clarity.

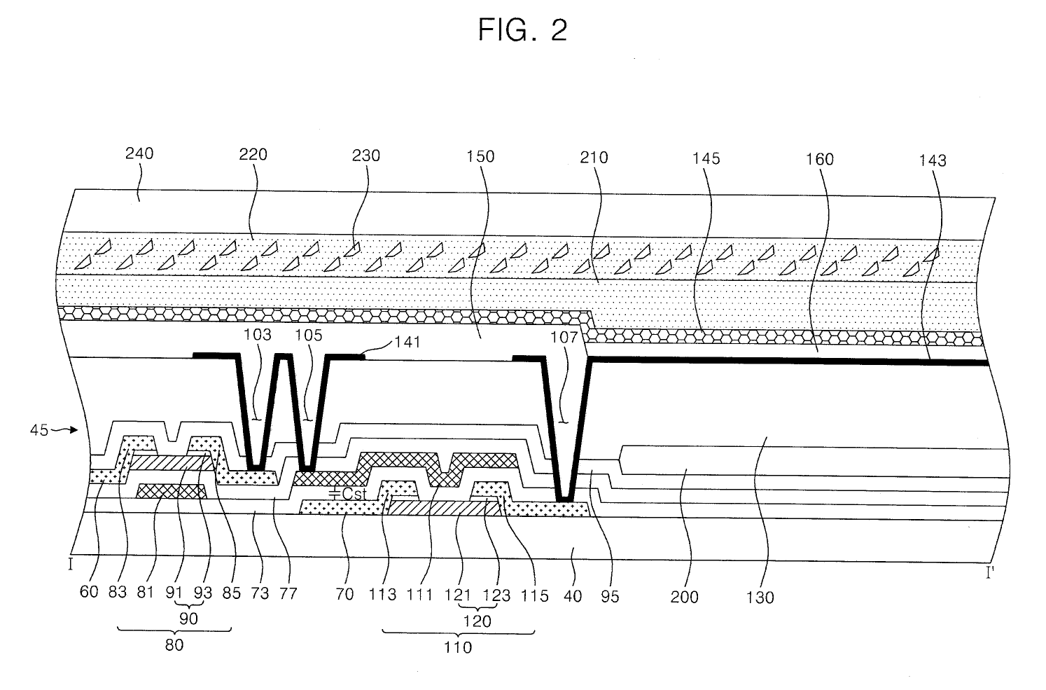

FIG. 1 is a plan view of a first organic light emitting display (OLED) device in accordance with the present disclosure, and FIG. 2 is a cross-sectional view taken along line I-I′ of FIG. 1.

Referring to FIGS. 1 and 2, the OLED device includes an organic light emitting pixel unit 45 (FIG. 2) formed on a transparent substrate 40 and including a gate line 50, a data line 60, a power line 70, a first thin film transistor (switching TFT) 80, a second thin film transistor (driving TFT) 110, a first electrode 143, an organic light emitting layer 160, and a second electrode 145. As seen in FIG. 2, the second electrode 145 is disposed above the first electrode 143 (e.g., a light transmitting electrode 143 such as made of ITO) and the organic light emitting layer 160 is sandwiched between them. The OLED device of the present disclosure also includes first and second protective layers 210 and 220, and a protective substrate 240. As will be detailed below, the first protective layers 210 is substantially free of desiccant particles while the second protective layer 220 includes such particles.

The substrate 40, on which a plurality of pixel units are arranged in a matrix form, may be formed of a transparent and electrically insulating material such as glass or plastic so that light transmits through the pixels.

The gate line 50 supplies a gate signal to the switching TFT 80, the data line 60 supplies a data signal to the switching TFT 80, and the power line 70 supplies a power signal to the driving TFT 110.

The switching TFT 80 is turned on when the gate line 50 is supplied with an activating gate signal so that the switching TFT 80 is rendered conductive to supply the data signal applied to the data line 60 to a storage capacitor Cst and a second gate electrode 111 of the driving TFT 110. For this purpose, the switching TFT 80 includes a first gate electrode 81 connected to the gate line 50, a first source electrode 83 connected to the data line 60, a first drain electrode 85 facing the first source electrode 83 and connected to a second gate electrode 111 of the driving TFT 110 and the storage capacitor Cst, and a first semiconductor pattern 90 defining a channel portion between the first source electrode 83 and the first drain electrode 85. The first semiconductor pattern 90 includes a first active layer 91 overlapping the first gate electrode 81 with a second gate insulating layer 77 disposed therebetween, and a first ohmic contact layer 93 formed on the first active layer 91 except for the channel portion to form an ohmic contact with the first source electrode 83 and the first drain electrode 85. The first active layer 91 may be formed of polysilicon or other forms of silicon (e.g., amorphous). In one embodiment, the first semiconductor layer 91 is formed of amorphous silicon which is advantageous to the on-off operation in view of desired characteristics of the switching TFT 80 which requires excellent discrete on-off characteristics.

The driving TFT 110 controls electric current supplied from the power line 70 to an organic light emitting cell, which will be described later, in response to the data signal applied to the second gate electrode 111 thereof, thus adjusting the light emitting amount of the organic light emitting cell. For this, the driving TFT 110 includes the second gate electrode 111 connected to the first drain electrode 85 through a connection electrode 141, a second source electrode 113 connected to the power line 70, a second drain electrode 115 facing the second source electrode 113 and connected to a first electrode 143 of the organic light emitting cell, and a second conductive pattern 120 forming a channel portion between the second source electrode 113 and the second drain electrode 115. The connection electrode 141 is formed of the same material as the first electrode 143 on a planarization layer 130. The connection electrode 141 connects the first drain electrode 85 of the switching TFT 80 exposed through a first contact hole 103 to the second gate electrode 111 of the driving TFT 110 exposed through a second contact hole 105. The first contact hole 103 penetrates a passivation layer 95 and the planarization layer 130 to expose the first drain electrode 85, and the second contact hole 105 penetrates the second gate insulating layer 77, the passivation layer 95 and the planarization layer 130 to expose the second gate electrode 111.

The second semiconductor pattern 120 includes a second active layer 121 overlapping the second gate electrode 111 with a first gate insulating layer 73 disposed therebetween, and a second ohmic contact layer 123 formed on the second active layer 121 except for the channel portion to form an ohmic contact with the second source electrode 113 and the second drain electrode 115. Such a second active layer 121 may be formed of amorphous silicon for example.

The second active layer 121 may alternatively be formed of polysilicon in view of the desired operating characteristics of the driving TFT 110 in which an electric current flows continuously during the frame-long light emission period of the organic light emitting cell.

The second gate electrode 111 of the driving TFT 110 overlaps the power line 70 with the second gate insulating layer 77, thus forming the storage capacitor Cst. Such a storage capacitor Cst helps to supply a constant current to the driving TFT 110 by maintaining the gate 111 of the driving TFT 110 with the charged voltage of the storage capacitor Cst until a data signal of the next frame is supplied so that the organic light emitting cell maintains the light emission, even though the switching TFT 80 is turned off in the interim.

The organic light emitting cell includes the first electrode 143 formed of a transparent conductive material on the planarization layer 130, an organic light emitting layer 160 including an emissive layer formed on the first electrode 143, and a second electrode 145 formed on the organic light emitting layer 160. Although not shown in detail, the organic light emitting layer 160 includes a hole injection layer, a hole transport layer, an optically emissive layer, an electron transport layer, and an electron injection layer, stacked in the recited order on the upper surface of the first electrode 143. The emissive layer may be formed in a triple layer structure in which emissive layers displaying red (R), green (G) and blue (B) colors are sequentially stacked, or in a double layer structure in which emissive layers having a complementary color relationship are stacked, or in a single layer structure composed of an emissive layer emitting a white color. Accordingly, the emissive layer provided in the organic light emitting layer 160 emits light in accordance with (e.g., in proportion to) the amount of the current applied to the second electrode 145 and the light of the organic light emitting layer 160 is transmitted toward a color filter 200 by way of the first electrode 143.

The first electrode 143 faces the second electrode 145 with the organic light emitting layer 160 disposed therebetween and formed every sub-pixel region. The first electrode 143 is formed independently in each sub-pixel region on the planarization layer 130. The first electrode 143 is coupled to the second drain electrode 115 of the driving TFT 110 exposed by a third contact hole 107 formed by etching the first and second gate insulating layers 73 and 77, the passivation layer 95, and the planarization layer 130. The first electrode 143 may be formed of a transparent conductive material such as indium tin oxide (ITO), indium zinc oxide (IZO), tin oxide (TO), or indium tin zinc oxide (ITZO).

A barrier layer 150 is formed on the upper surface of the connection electrode 141 connected to the planarization layer 130. The barrier layer 150 is is formed of an organic material to serve as an insulating layer. The barrier layer 150 is patterned (e.g., opened up near hole 107) to expose the first electrode 143 such that the organic light emitting layer 160 is positioned on the upper surface of the first electrode 143.

The second electrode 145 may be formed of aluminum (Al), magnesium (Mg), silver (Ag), or calcium (Ca) having excellent electron transport capability and good reflection performance.

The color filter 200 is formed to overlap the organic light emitting layer 160 generating white light on the upper surface of the passivation layer 95. Accordingly, the color filter 200 displays red (R), green (G) and blue (B) colors using the white light produced from the organic light emitting layer 160. The R, G or B light generated from the color filter 200 is emitted to the outside through the transparent substrate 40.

The first protective layer 210 is formed to extend above and across the overall surface of the substrate 40. In one embodiment, the first protective layer 210 is formed of an epoxy-based conformal sealant in order to prevent moisture and/or oxygen from penetrating from the outside and to protect the organic light emitting pixel unit 45 from various impacts. For example, the epoxy-based sealant may be formed of at least one member selected from the group consisting of bisphenol type epoxy resin, epoxidized butadiene resin, fluorine type epoxy resin, and novolac type epoxy resin.

The first protective layer 210 has a thickness greater than a step height of the second electrode 145 formed by the barrier layer 150 in order to reduce the step height, and the upper surface thereof is formed substantially planar (horizontally). The reason for this is to eliminate any space in which moisture or gas, which can cause damage to the organic light emitting layer 160 might be trapped due to respective layers to be stacked later on top of barrier layer 150 during mass production manufacture.

The second protective layer 220 is formed on the overall surface of the substrate 40 over the first protective layer 210. Like the first protective layer 210, the second protective layer 220 is formed of an epoxy-based sealant in order to prevent moisture or oxygen from penetrating from the outside. For example, the epoxy-based sealant may be formed of at least one member selected from the group consisting of bisphenol type epoxy resin, epoxidized butadiene resin, fluorine type epoxy resin, and novolac type epoxy resin.

However, unlike the first protective layer 210, the second protective layer 220 comprises desiccant particles 230 (e.g., of average diameter of 5 microns) for absorbing moisture, distributed uniformly across the overall surface of the substrate 40. The desiccant particles 230 act as fillers for removing moisture that manages to penetrate from the outside. For example, the desiccant particles 230 may be formed of one or more moisture absorbing materials such as talc, which do not exhibit any substantial swelling property when exposed to water or organic solution. Moreover, silica gel may be included as the desiccant member 230. In this case, the desiccant particles 230 should have a thickness (measured vertically in FIG. 2) of a size smaller than the thickness of the second protective layer 220 (or vise versa, the second protective layer 220 should have a thickness equal to or greater than the normally largest ones of the desiccant particles expected to be found in the first protective layer 210). For example, the largest normal ones of the desiccant particles 230 may have a size (e.g., diameter) of less than about 5 μm, when the second protective layer 220 has a thickness of about 20 μm.

The first and second protective layers 210 and 220 are structured to prevent an electrical failure from occurring in which the second electrode 145 is spot depressed into shorting contact with the first electrode 143, due to a depression force exerted by an overlying desiccant member 230 of large size (overlying in FIG. 2), of which description will be given in connection with the protective substrate 240 below.

The protective substrate 240 is positioned on the upper surface of the second protective layer 220 to protect the organic light emitting pixel unit 45 from an external impact. The protective substrate 240 helps to prevent moisture or oxygen from penetrating from the outside together with the first and second protective layers 210 and 220. Such a protective substrate 240 may be formed of a transparent insulating material such as glass or plastic, the same as the substrate 40. The material of the protective substrate 240 is not limited to glass or plastic, but may be formed of various other materials such as an organic, inorganic or metallic material.

The protective substrate 240 is compressively bonded to the second protective layer 220. The protective substrate 240 pressurizes the second protective layer 220 during the assembly process, thus potentially causing the depression of an underlying layer by particles of the desiccant members population 230 if the intervening first protective layer 210 were not present. However, at this time, the first protective layer 210 formed below the bottom of the second protective layer 220 acts to relieve the stress and strain of spot depressions caused by large ones of the desiccant particles 230, thus preventing the undesirable spot depression of the second electrode 145 into shorting contact with the first electrode 143. Accordingly, it is possible to prevent an electrical failure caused by the contact between the second electrode 145 and the first electrode 143.

In the following, the first and second protective layers 210 and 220 in accordance with the exemplary embodiments of the present disclosure will be described in more detail.

In the first exemplary embodiment of the OLED device in accordance with the present disclosure, the first protective layer 210 and the second protective layer 220, disposed between the organic light emitting pixel unit 45 and the protective substrate 240, are formed of a same material except that the first protective layer 210 is substantially free of large desiccant particles 230 whereas the second protective layer 220 has such particles 230 substantially uniformly distributed throughout. For example, the first protective layer 210 and the second protective layer 220 may be formed of a sealant made of any one member selected from the group consisting of bisphenol type epoxy resin, epoxidized butadiene resin, fluorine type epoxy resin, and novolac type epoxy resin. And as mentioned, the second protective layer 220 further includes the desiccant particles 230 such as talc. The first protective layer 210 serves as a stress buffering layer for preventing damage to the organic light emitting pixel unit 45 from an external impact and relieving the pressure from the top. The second protective layer 220 bonds to the protective substrate 240 and serves as a desiccant layer for preventing deeper penetration of moisture which manages to enter from the outside through, for example, the protective substrate 240.

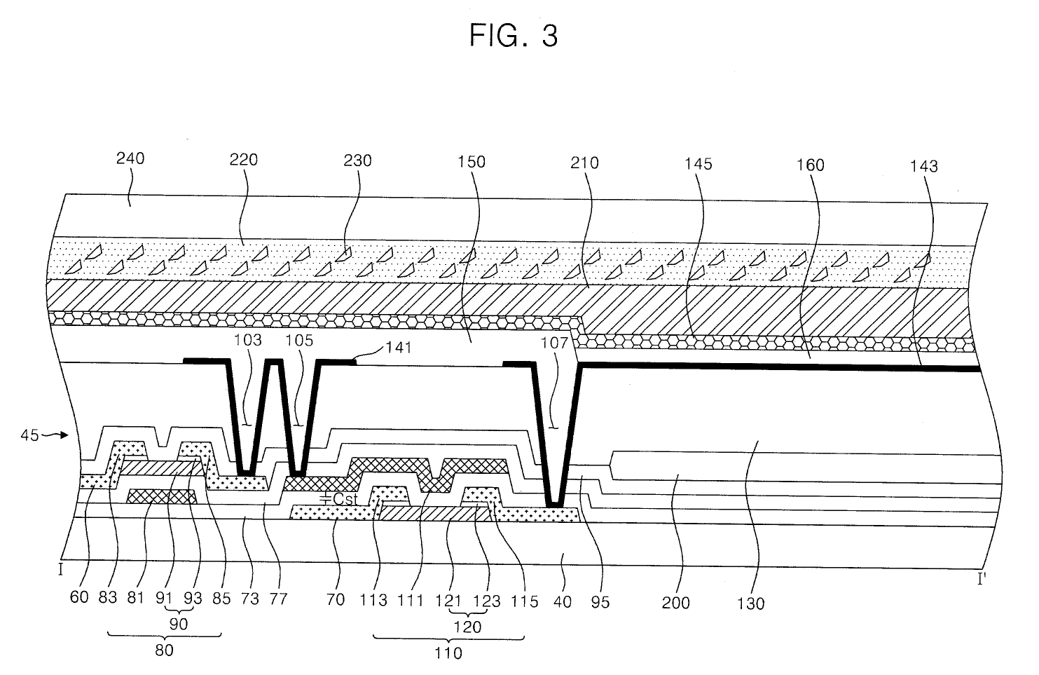

FIG. 3 is a cross-sectional view of an OLED device in accordance with a second exemplary embodiment. The same elements as those shown in FIGS. 2 and 3 are identified by the same reference numerals and descriptions of unchanged ones will be omitted.

As shown in FIG. 3, in the OLED device in accordance with the second exemplary embodiment, the first protective layer 210 and the second protective layer 220, disposed between the organic light emitting pixel unit 45 and the protective substrate 240, are formed of different materials. For example, the first protective layer 210 and the second protective layer 220 are formed of different epoxy-based sealants. Moreover, the second protective layer 220 further includes the desiccant particles 230 while the first protective layer 210 is substantially free of any or of desiccant particles like 230. That is, the first protective layer 210 is formed of a first sealant, and the second protective layer 220 is formed of a different second sealant as well as including the desiccant particles 230.

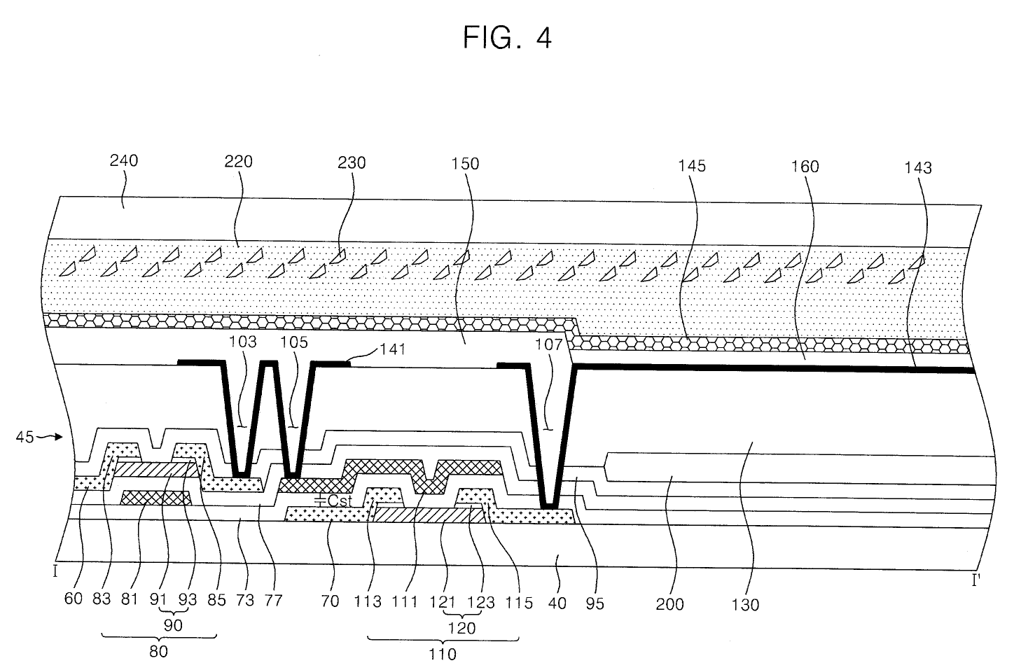

FIG. 4 is a cross-sectional view of an OLED device in accordance with a third exemplary embodiment. The same elements as those shown in FIGS. 2 and 4 are identified by the same reference numerals and descriptions of unchanged ones will be omitted.

As shown in FIG. 4, in the OLED device in accordance with the third exemplary embodiment, the second protective layer 220 including the desiccant particles 230 is formed on the upper surface of the second electrode 145. Here, the second protective layer 220 is formed of an epoxy-based sealant but it has a nonuniform distribution of desiccant particles 230 in the vertical direction such that larger desiccant particles 230 appear near the top and essentially no desiccant particles (or only very small diameter ones) appear near the bottom of layer 220. In one example, the second protective layer 220 may be formed of a sealant made of any one member selected from the group consisting of bisphenol type epoxy resin, epoxidized butadiene resin, fluorine type epoxy resin, and novolac type epoxy resin.

Moreover, as mentioned the desiccant particles 230 are distributed vertically so as to be spaced apart from the second electrode 145 at least at predetermined intervals in the second protective layer 220. Especially, the desiccant particles 230 in the second protective layer 220 on the upper surface of the organic light emitting cell are disposed at a predetermined height from the second electrode 145 so that the desiccant-free or desiccant-light bottom portion of layer 220 functions as a buffer against excessive spot deformation of the second electrode 145. In one case, the desiccant particles 230 may be arranged at a height such that the desiccant particles 230 do not cause a depression of the second electrode 145 due to the pressure from the top. For example, the second protective layer 220 is formed such that the desiccant particles 230 are distributed at a height of at least about 5 μm from the second electrode 145. During the formation of the second protective layer 220, shrinkage of about 5 μm may occur through a curing process. The shrinkage of the second protective layer 220 makes the desiccant particles 230 to be close to the surface of the second electrode 145. Accordingly, the desiccant particles 230 included in the second protective layer 220 may be distributed at a height of at least about 5 μm from the second electrode 145.

Meanwhile, if a step height of more than about 5 μm is formed in the second electrode 145 by the barrier layer 150 disposed therebelow, the desiccant particles 230 may be distributed at a height within about 5 μm from the second electrode 145 on the barrier layer 150. Since the desiccant particles 230 disposed on the upper surface of the barrier layer 150 do not cause the depression of the second electrode 145 in that stepped up region, it is allowed that the desiccant particles 230 are positioned within about 5 μm or less.

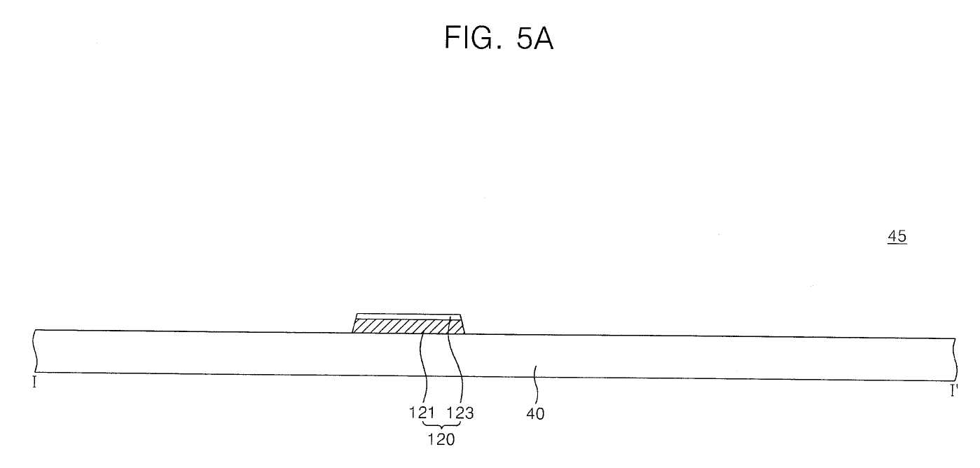

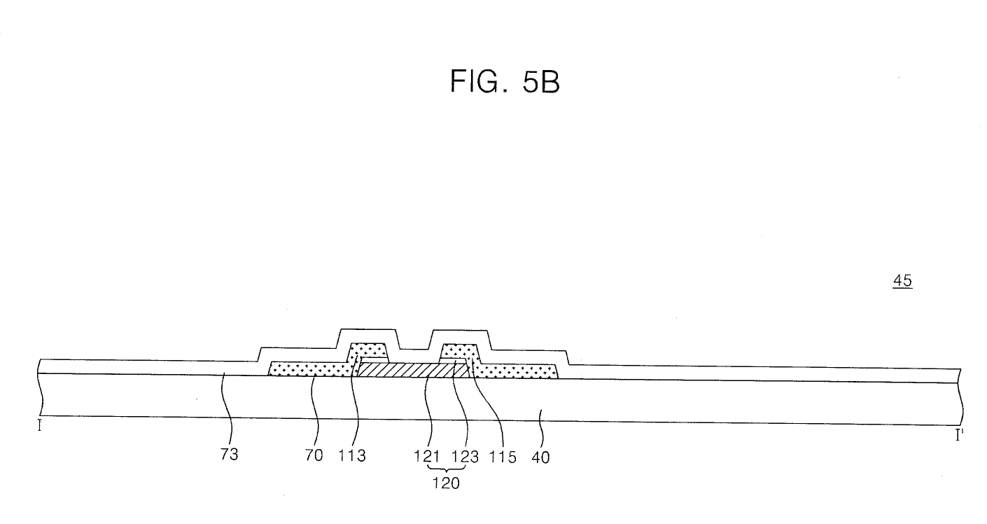

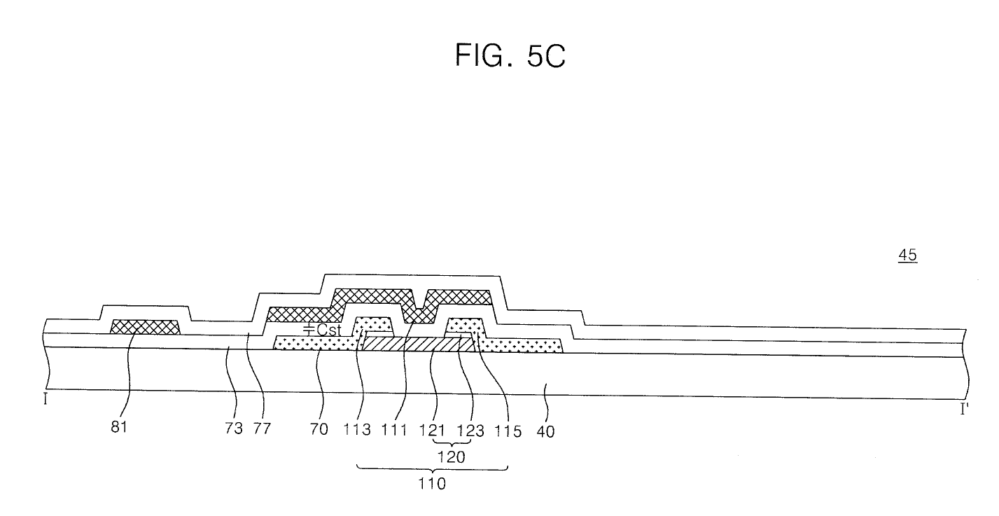

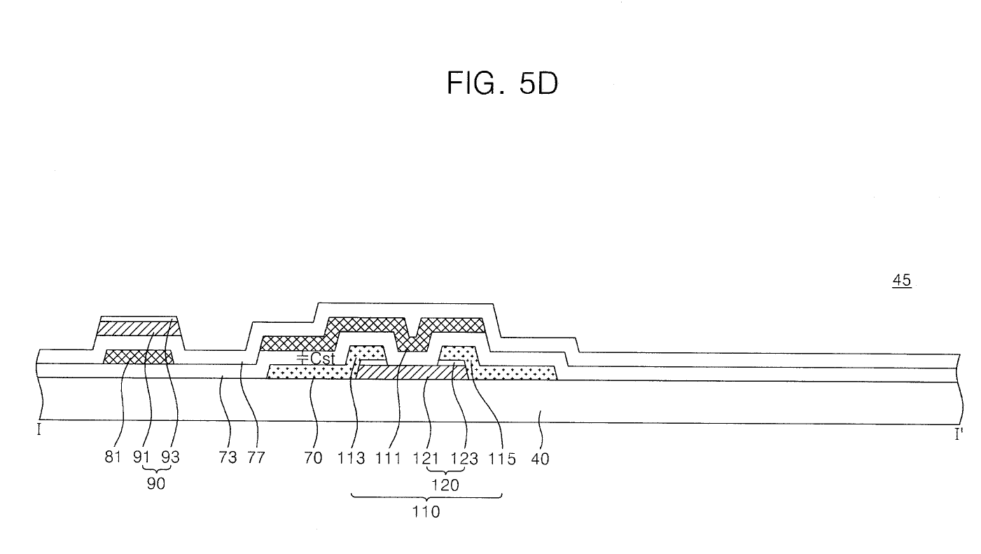

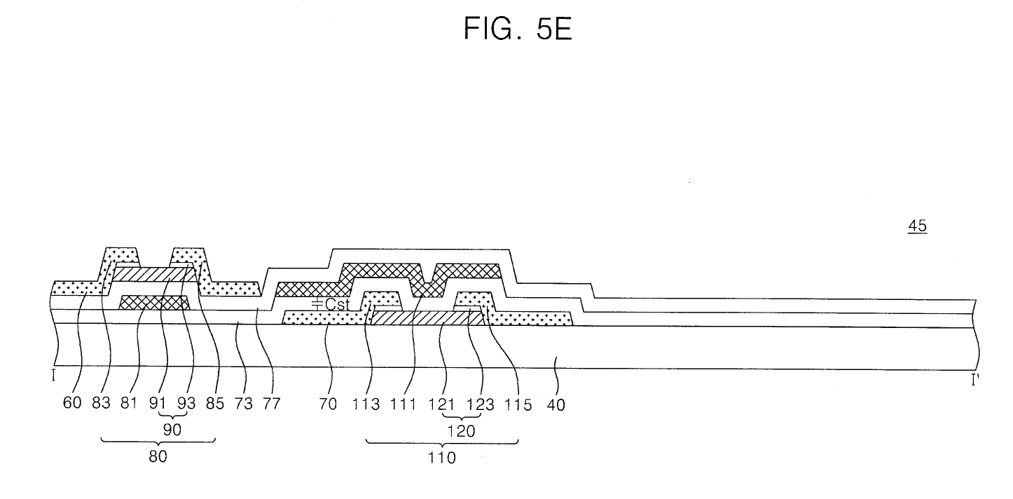

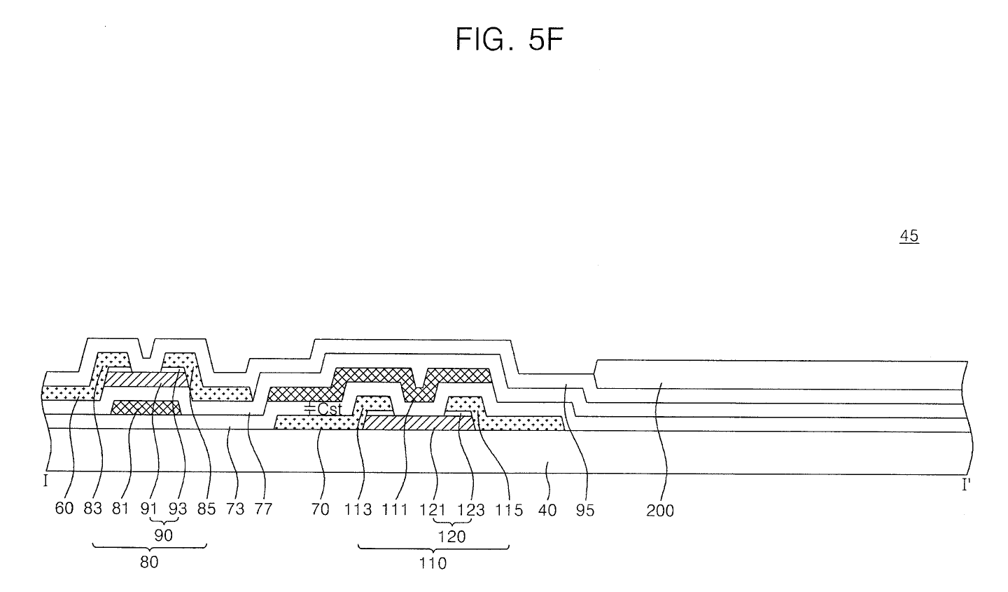

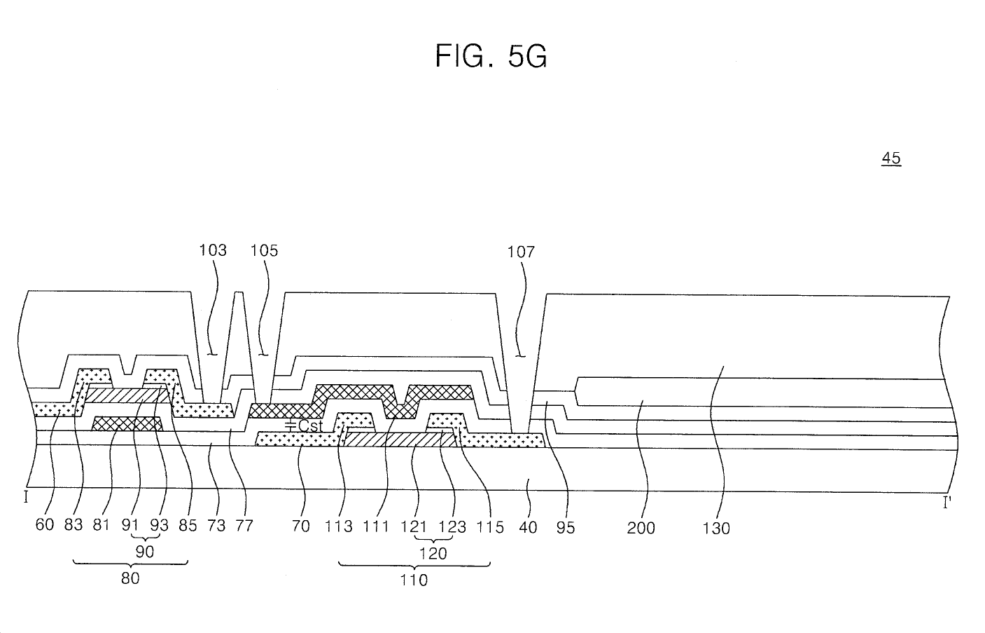

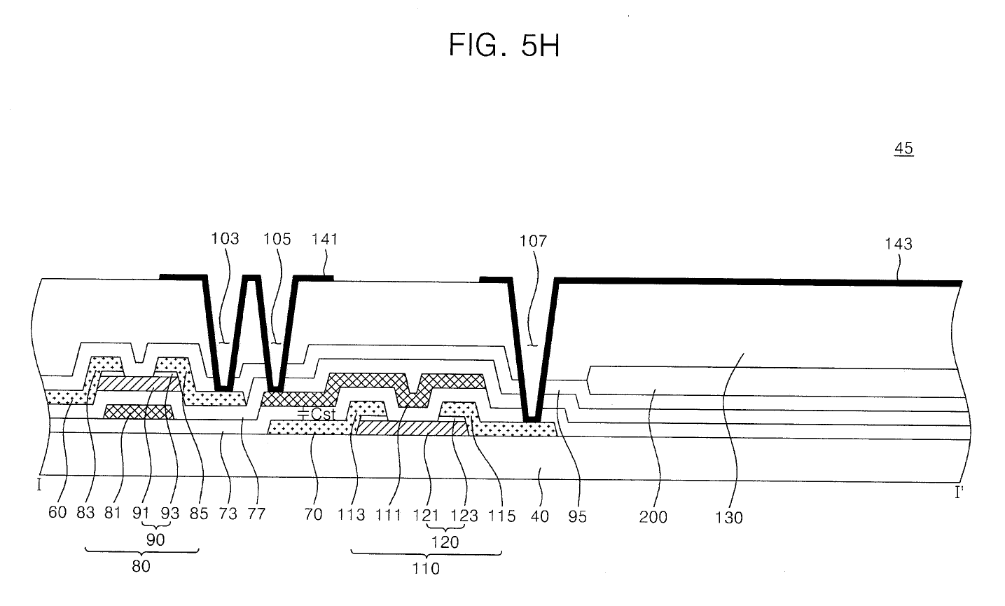

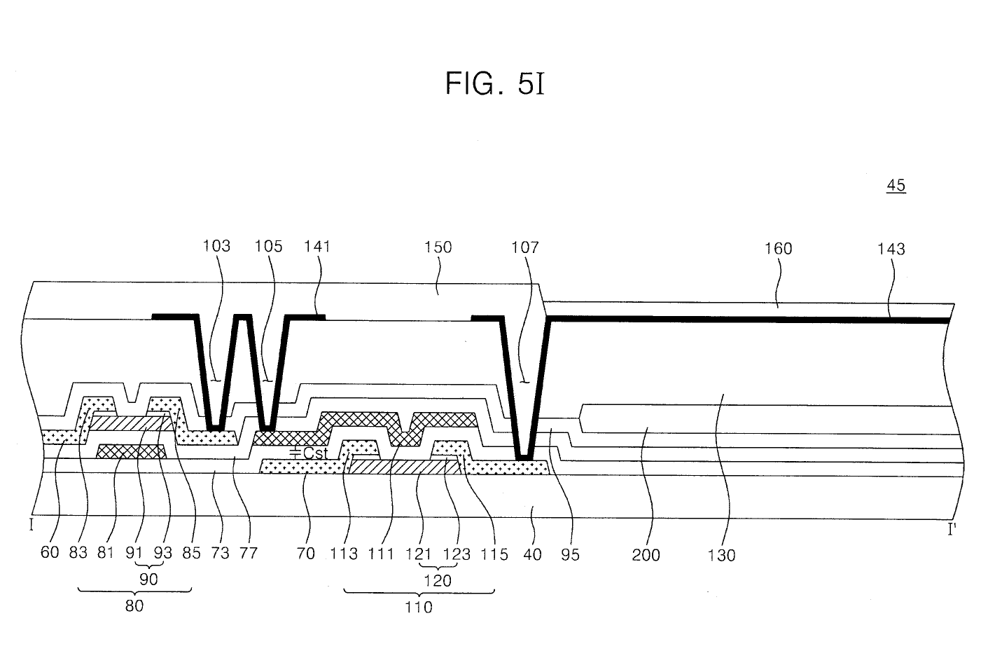

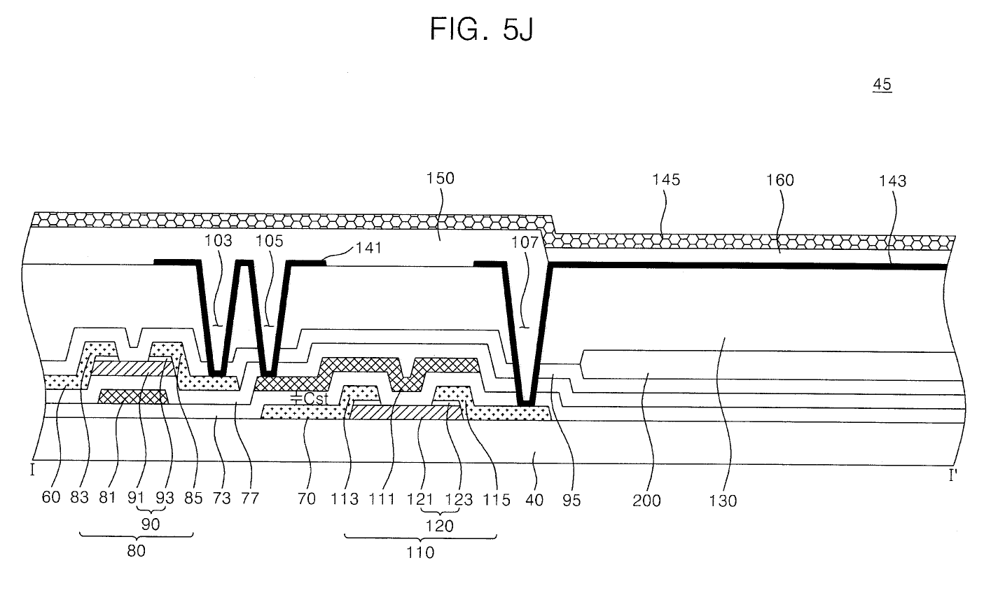

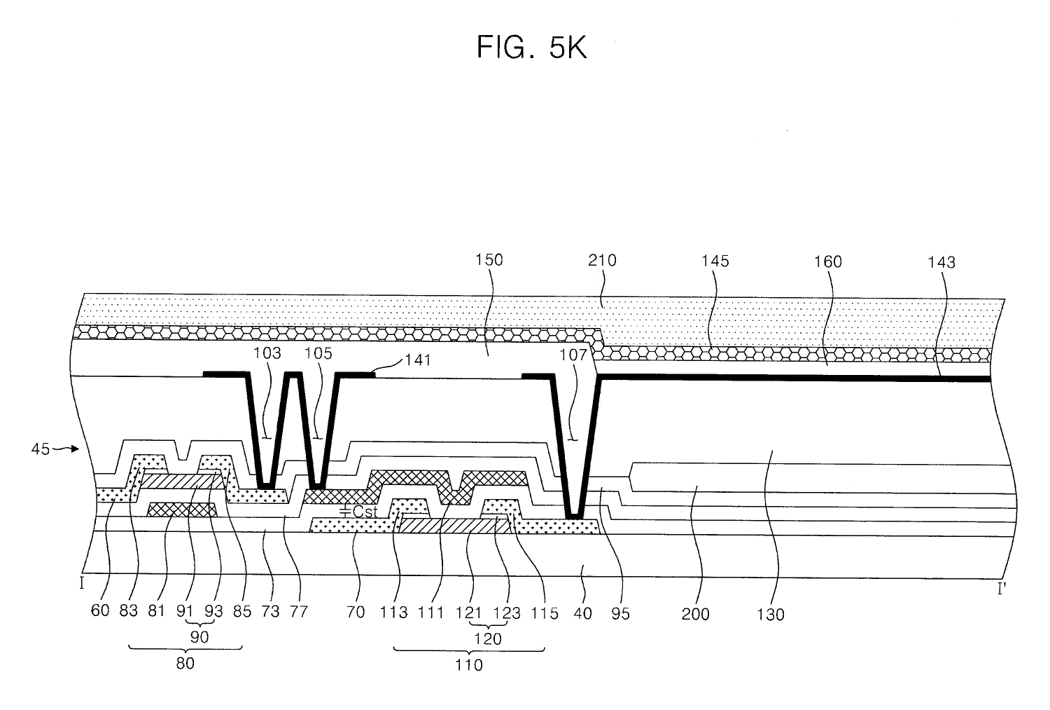

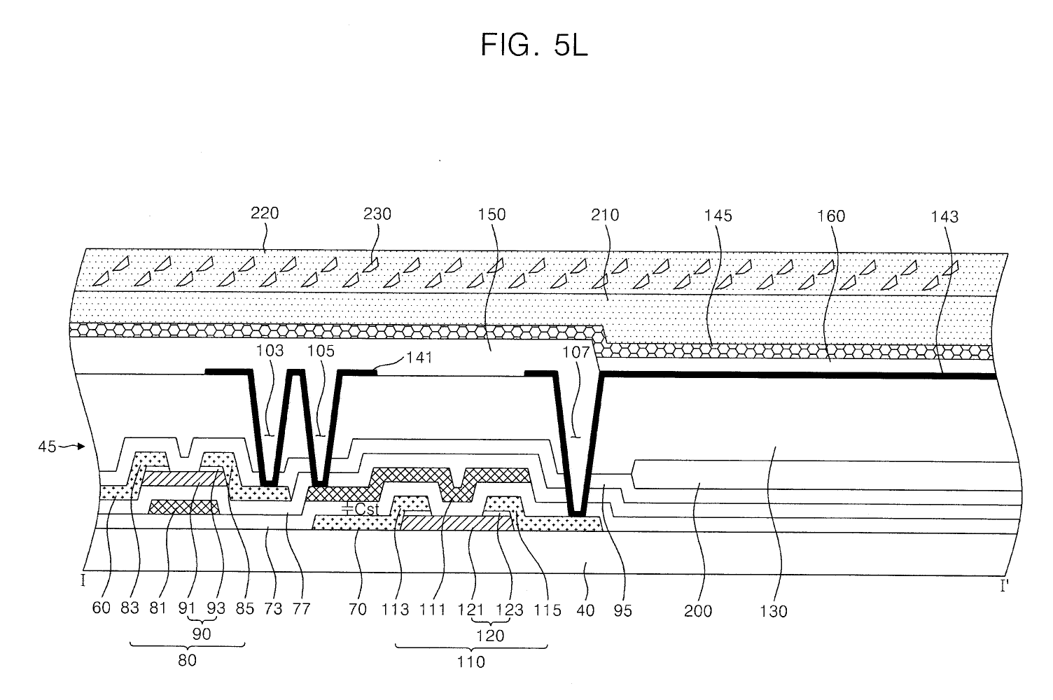

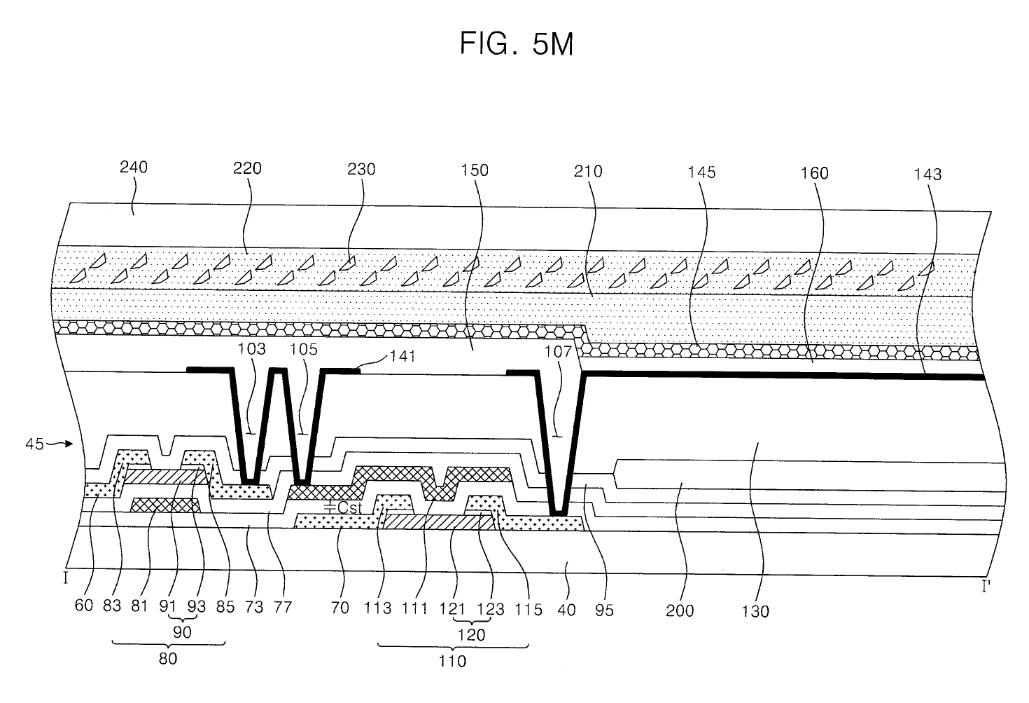

Next, a method of manufacturing an OLED device in accordance with the present disclosure will be described with reference to FIGS. 5A to 5M.

The method of manufacturing an OLED device in accordance with the present disclosure includes forming an organic light emitting pixel unit 45 on a transparent substrate 40, where the method includes forming a first protective layer 210 on the upper surface of the organic light emitting pixel unit 45 where the first protective layer 210 is substantially free of any desiccant particles 230, and forming a second protective layer 220 in which desiccant particles 230 are distributed uniformly or on a vertically graduated basis in the first protective layer 210.

First, the process of forming the organic light emitting pixel unit 45 will be described with reference to FIG. 5A below.

As shown in FIG. 5A, a second semiconductor pattern 120 including a second active layer 121 of a driving TFT 110 and a second ohmic contact layer 123 is formed on a substrate 40. The second active layer 121 and the second ohmic contact layer 123 are formed of polysilicon in view of the desired characteristics of the driving TFT 110. The process of forming the second active layer 121 will be described in more detail below. First, amorphous silicon and n⁺ doped amorphous silicon are deposited on the overall surface of the substrate 40 in a uniform thickness and then re-crystallized into polycrystalline form by laser irradiation or solid phase crystallization using heat and a magnetic field. The solid phase crystallization is typically used for the crystallization of a large-area substrate. The poly-crystallized silicon layer is patterned by photolithography and etching processes, thus forming the second active layer 121 and the second ohmic contact layer 123 as shown in FIG. 5A.

Subsequently, as shown in FIG. 5B, a driving metal pattern including a power line 70, a second source electrode 113 and a second drain electrode 115 is formed thereon. More specifically, a conductive metal is deposited on the overall surface of the substrate 40 by a sputtering method and patterned by photolithography and etching processes, thus forming the power line 70, the second source electrode 113 and the second drain electrode 115. At this time, the second ohmic contact layer 123 which is not covered but exposed by the second source electrode 113 and the second drain electrode 115 is removed by an etching process to form a channel formed of amorphous silicon only.

Next, a first gate insulating layer 73 is formed on the overall surface of the substrate 40. The first gate insulating layer 73 is formed by depositing an inorganic insulating material such as silicon oxide (SiOx), silicon nitride (SiNx), or the like on the overall surface of the substrate 40 by a deposition method such as plasma enhanced chemical vapor deposition (PECVD).

As shown in FIG. 5C, a gate metal pattern including a first gate electrode 81, a second gate electrode 111 and a gate line 50 is formed on the first gate insulating layer 73. Moreover, a second gate insulating layer 77 is formed on the upper surface of the gate metal pattern.

More specifically, a conductive metal is deposited on the upper surface of the first gate insulating layer 73 by a sputtering method and then patterned by photolithography and etching processes, thus forming the first and second gate electrodes 81 and 111. At this time, the gate line 50 is formed simultaneously with the formation of the first gate electrode 81.

Subsequently, the second gate insulating layer 77 is deposited on the overall surface of the substrate 40 on which the first and second gate electrodes 81 and 111 are formed. Since the second gate insulating layer 77 is formed in the same manner as the first gate insulating layer 73, a detailed description will be omitted.

As shown in FIG. 5D, a first semiconductor pattern 90 including a first active layer 91 and a first ohmic contact layer 93 is formed on the second gate insulating layer 77. The first active layer 91 and the first ohmic contact layer 93 are formed of amorphous silicon in view of the desired characteristics of a switching TFT 80. Accordingly, an amorphous silicon layer is deposited on the substrate 40 and patterned by photolithography and etching processes, not subjected to a re-crystallization process, thus forming the first active layer 91 and the first ohmic contact layer 93.

Next, as shown in FIG. 5E, a data metal pattern including a data line 60, a first source electrode 83 and a first drain electrode 85 is formed on the substrate 40 on which the first semiconductor pattern 90 is formed. Since the process of forming the first source electrode 83 and the first drain electrode 85 is the same as that of the second source electrode 113 and the second drain electrode 115, a detailed description will be omitted.

Subsequently, as shown in FIG. 5F, a passivation layer 95 is formed on the substrate 40 on which the data metal pattern is formed, and a color filter 200 including R, G and B color filter elements is formed on the passivation layer 95.

The passivation layer 95 is formed by stacking an inorganic insulating material such as silicon oxide (SiOx), silicon nitride (SiNx), or the like on the substrate 40 on which the data metal pattern is formed. The color filter 200 is formed in such a manner that R, G and B pigments are stacked in each sub-pixel on the substrate 40, on which the passivation layer 95 is formed, and then patterned by photolithography and etching processes.

Then, as shown in FIG. 5G, a planarization layer 130 including first to third contact holes 103, 105 and 107 is formed on the upper surface of the passivation layer 95 and the color filter 200.

The planarization layer 130 may be formed by a spin coating or spinless coating method on the substrate 40 on which the passivation layer 95 is formed. The first to third contact holes 103, 105 and 107 are then formed by selectively patterning at least two layers of the first and second gate insulating layers 73 and 77, the passivation layer 95, and the planarization layer 130 by photolithography and etching processes. The first contact hole 103 penetrates the passivation layer 95 and the planarization layer 130 to expose the first drain electrode 85 of the switching TFT 80. The second contact hole 105 penetrates the second gate insulating layer 77, the passivation layer 95 and the planarization layer 130 to expose the second gate electrode 111 of the driving TFT 110. The third contact hole 107 penetrates the first and second gate insulating layers 73 and 77, the passivation layer 95 and the planarization layer 130 to expose the second drain electrode 115 of the driving TFT 110.

Next, as shown in FIG. 5H, a transparent conductive pattern including a connection electrode 141 and a first electrode 143 is formed on the substrate 40 on which the planarization layer 130 is formed.

The transparent conductive pattern is formed on the substrate 40, on which the planarization layer 130 is formed, by a deposition method such as sputtering and then patterned by photolithography and etching processes. The transparent conductive layer may comprise ITO, IZO, TO, and/or ITZO.

Subsequently, as shown in FIG. 51, a barrier layer 150 is formed on the substrate 40 on which the planarization layer 130 and the connection electrode 141 are formed, and an organic light emitting layer 160 is formed on an upper surface of the first electrode 143.

The barrier layer 150 is formed in such a manner that an organic insulating material is deposited on the upper surface of the planarization layer 130 and the transparent conductive pattern and then patterned by photolithography and etching processes. At this time, the barrier layer 150 is patterned to define a pixel through-hole through which the first electrode 143 is exposed.

Next, the organic light emitting layer 160 is formed on the pixel hole through which the first electrode 143 is exposed. An emissive layer included in the organic light emitting layer 160 may be formed in a triple layer structure in which emissive layers displaying R, G and B are sequentially stacked, in a double layer structure in which emissive layers having a complementary color relationship are stacked, or in a single layer structure composed of emissive layers displaying R, G and B colors, respectively.

As shown in FIG. 5J, a second electrode 145 is formed on the substrate 40 on which the organic light emitting layer 160 is formed.

The second electrode 145 may be formed by depositing a metal layer on the upper surface of the barrier layer 150 and the organic light emitting layer 160. The second electrode 145 is formed of Al, Mg, Ag, or Ca having excellent reflectivity in order to reflect light incident from the organic light emitting layer 160.

Next, the process of forming the first protective layer 210 on the organic light emitting pixel unit 45 and the process of forming the second protective layer 220 on the first protective layer 210 will be described with reference to FIGS. 5K and 5L below.

As shown in FIG. 5K, the first protective layer 210 is formed on the substrate 40 on which the second electrode 145 is formed.

The first protective layer 210 is formed on the overall surface of the substrate 40 over the second electrode 145. The first protective layer 210, which is substantially free of any or of desiccant particles, is formed on the upper surface of the second electrode 145 using a sealant made of any one selected from the group consisting of bisphenol type epoxy resin, epoxidized butadiene resin, fluorine type epoxy resin, and novolac type epoxy resin. Moreover, the first protective layer 210 is formed with a thickness greater than a step height of the second electrode 145 formed by the barrier layer 150 to reduce the step height, and the upper surface thereof is formed horizontally to prevent moisture or gas from penetrating between respective layers to be stacked or bonded later. At this time, the first protective layer 210 is formed on the upper surface of the second electrode 145 by a screen printing method or a dispensing method in view of the viscosity of the sealant.

Subsequently, as shown in FIG. 5L, the second protective layer 220 is formed on the substrate 40 on which the first protective layer 210 is formed.

The second protective layer 220 is formed on the overall surface of the substrate 40 over the first protective layer 210. The second protective layer 220 is formed of an epoxy-based sealant, like the first protective layer 210. Moreover, the second protective layer 220 comprises the large-sized desiccant particles 230 such as talc, silica gel, or other non-swelling desiccant particles usable to prevent the further penetration of moisture that managed to get in from the outside. The second protective layer 220 is formed such that the desiccant particles 230 are distributed uniformly in the horizontal directions across the overall surface of the substrate 40. Furthermore, the second protective layer 220 is formed to have a planar top surface and/or a constant thickness such that a protective substrate 240 can be bonded thereto accurately later.

The method of manufacturing an OLED device in accordance with the present disclosure further includes bonding the protective substrate 240, which will be described with reference to FIG. 5M below.

As shown in FIG. 5M, the protective substrate 240 is bonded to the upper surface of the second protective layer 220. The protective substrate 240 is formed of an insulating material such as glass or plastic, like the substrate 40. The protective substrate 240 is bonded thereto by pressurizing the second protective layer 220. After bonding the protective substrate 240 to the second protective layer 220, the first protective layer 210 and the second protective layer 220 are cured to finish the OLED device.

The process of forming the first and second protective layers 210 and 220 in accordance with the present disclosure is not limited to those described above with reference to FIGS. 5K and 5L. For example, the first protective layer 210 may be formed on the substrate 40 on which the organic light emitting pixel unit 45 is formed, the second protective layer 220 may be formed on the protective substrate 240, and then the first and second protective layers 210 and 220 may be bonded to each other. In this case, the denser desiccant particles 230 included in the second protective layer 220 are slowly settled down and move onto the surface of the protective substrate 240. With such desiccant particles 230 moving onto the surface of the protective substrate 240, it is possible to prevent the situation where the larger desiccant particles in the second protective layer 220 damage the second electrode 145 by pressurizing of the first protective layer 210 while the second protective layer 220 is bonded to the first protective layer 210.

Subsequently, the first protective layer 210 formed on the substrate 40 and the second protective layer 220 formed on the protective substrate 240 are bonded to each other and then cured.

Examples of materials used in forming the first protective layer 210 and the second protective layer 220 in the method of manufacturing an OLED device in accordance with the present disclosure will be described below.

According to one method of manufacturing an OLED device in accordance with a first exemplary embodiment of the present disclosure, the first protective layer 210 and the second protective layer 220 are formed using a same sealant material. For example, the first protective layer 210 is formed of a sealant made of any one member selected from the group consisting of bisphenol type epoxy resin, epoxidized butadiene resin, fluorine type epoxy resin, and novolac type epoxy resin. The second protective layer 220 including the desiccant particles 230 such as talc, silica gel, etc is formed of the same sealant as the first protective layer 210 on the upper surface of the first protective layer 210.

According to a second method of manufacturing an OLED device in accordance with a second embodiment of the present disclosure, the first protective layer 210 and the second protective layer 220 are formed using different sealant materials. For example, the first protective layer 210 is formed of a sealant made of any one selected from the group consisting of bisphenol type epoxy resin, epoxidized butadiene resin, fluorine type epoxy resin, and novolac type epoxy resin. The second protective layer 220 including the desiccant particles 230 is formed of a sealant different from that of the first protective layer 210 on the upper surface of the first protective layer 210.

As described above, the OLED device in accordance with the present disclosure includes the first protective layer and the second protective layer including the desiccant particles formed on the upper surface of the organic light emitting diode using an epoxy-based sealant. The first protective layer is formed with a predetermined thickness on the upper surface of the second electrode of the organic light emitting pixel unit to prevent or reduce excessive spot depression of the underlying layer caused by the desiccant particles included in the second protective layer. Accordingly, it is possible to prevent an electrical failure in which the second electrode is spot depressed into shorting contact with the first electrode, and a pixel defect in which pixels do not emit light.

Although the present disclosure has been described with reference to certain exemplary embodiments thereof, it will be understood by those skilled in the art that a variety of modifications and variations may be made to the present disclosure without departing from the spirit or scope of the present teachings.

What is claimed is:

1. An organic light emitting display device comprising:
an organic light emitting pixel unit having a first electrode, an organic light emitting layer, and a second electrode, the organic light emitting pixel unit being integrally formed on a substrate;
a first protective layer that is substantially free of desiccant particles being formed on the upper surface of the second electrode; and
a second protective layer, including desiccant particles being formed on the first protective layer.

2. The organic light emitting display device of claim 1, further comprising a protective substrate compressively bonded to the second protective layer.

3. The organic light emitting display device of claim 1, wherein the first protective layer is formed of a sealant that inhibits passage of moisture therethrough.

4. The organic light emitting display device of claim 3, wherein the second protective layer including the desiccant particles is formed of a sealant that inhibits passage of moisture therethrough.

5. The organic light emitting display device of claim 4, wherein the sealant of the first protective layer is formed of a same material as the sealant of the second protective layer.

6. The organic light emitting display device of claim 5, wherein the sealant of the first protective layer is formed of a same epoxy-based resin as the sealant of the second protective layer.

7. The organic light emitting display device of claim 4, wherein the sealant of the first protective layer is formed of a different material from the sealant of the second protective layer.

8. The organic light emitting display device of claim 7, wherein the sealant of the first protective layer is formed of a different epoxy-based resin from the sealant of the second protective layer.

9. The organic light emitting display device of claim 1, wherein the first protective layer is has a thickness substantially greater than a largest expected diameter of the desiccant particles in the second protective layer.

10. The organic light emitting display device of claim 1, wherein the desiccant particles are formed of at least one of a talc and a silica gel.

11. An organic light emitting display device comprising:
an organic light emitting pixel unit having a first electrode, an organic light emitting layer, and a second electrode, the pixel unit being formed on a substrate; and
a protective layer, including desiccant particles, formed on the upper surface of the second electrode,
wherein the desiccant particles are spaced by at least 5 μm apart from the upper surface of the second electrode.

12. The organic light emitting display device of claim 11, further comprising a protective substrate bonded to the substrate with the protective layer disposed therebetween.

13. A method of manufacturing an organic light emitting display device, the method comprising:
forming an organic light emitting pixel unit integrally on a substrate, the organic light emitting pixel unit including a driving thin film transistor, a switching thin film transistor, a first electrode, an organic light emitting layer, and a second electrode,
forming a first protective layer on an upper surface of the organic light emitting pixel unit where the first protective layer is substantially devoid of desiccant particles; and
forming a second protective layer in which desiccant particles are distributed within the second protective layer, where the second protective layer is formed on an upper surface of the first protective layer.

14. The method of claim 13, wherein forming the organic light emitting pixel unit comprises:
forming the driving thin film transistor and the switching thin film transistor on the substrate;
forming a passivation layer to cover the driving thin film transistor and the switching thin film transistor, and a color filter on the upper surface of the passivation layer;
forming a planarization layer including first to third contact holes on the upper surface of the passivation layer and the color filter;
forming a transparent conductive pattern including a connection electrode and the first electrode on the upper surface of the planarization layer;
forming a barrier layer on the upper surface of the planarization layer and the connection electrode, and the organic light emitting layer on the upper surface of the first electrode; and
forming the second electrode on the upper surface of the barrier layer and the organic light emitting layer.

15. The method of claim 14, further comprising
compressively bonding a protective substrate on the upper surface of the second protective layer, after forming the second protective layer.

16. The method of claim 14, wherein the first protective layer is formed of an anti-moisture sealant and is disposed on the upper surface of the second electrode.

17. The method of claim 16, wherein the second protective layer comprises an anti-moisture sealant and desiccant particles distributed therein.

18. The method of claim 17, wherein the sealant of the first protective layer is formed of a same epoxy-based resin as the sealant of the second protective layer.

19. The method of claim 17, wherein the sealant of the first protective layer is formed of a different epoxy-based resin from the sealant of the second protective layer.
